(19) United States
(12) Patent Application Publication
(10) Pub. No.: US 2013/0010823 A1
(43) Pub. Date: Jan. 10, 2013

(54) Quantum Cascade Laser with Optimized Voltage Defect

(76) Inventors: Richard Maulini, Los Angeles, CA (US); Arkadiy Lyakh, Santa Monica, CA (US); Alexei Tsekoun, Los Angeles, CA (US); C. Kumar N. Patel, Los Angeles, CA (US)

(21) Appl. No.: 13/542,461

(22) Filed: Jul. 5, 2012

Related U.S. Application Data
(60) Provisional application No. 61/504,499, filed on Jul. 5, 2011.

(51) Int. Cl. H01S 5/34

(52) U.S. Cl. 372/45.01

(57) ABSTRACT

A quantum cascade laser having a lower laser level backfilling given by an equation that accounts for the degeneracy of energy states due to the presence of multiple subbands. For mid-infrared quantum cascade lasers at room temperature and a typical number of injector subbands, the voltage defect is between 90 meV and 110 meV at a current density of 80% of the rollover current density.

### CROSS-REFERENCES TO RELATED APPLICATIONS

This patent application claims the benefit of U.S. Provisional Application Ser. No. 61/504,499 filed Jul. 5, 2011 for Quantum Cascade Lasers with Optimized Voltage Defect, and that application is incorporated here by this reference.

### TECHNICAL FIELD

This invention relates to quantum cascade lasers.

### BACKGROUND ART

Quantum cascade lasers (QCLs) are semiconductor lasers based on intersubband transitions in semiconductor heterostructures. At present, QCLs represent the leading semiconductor laser technology in the mid-infrared spectral range, between ˜3.5 and 17 microns, in terms of wallplug efficiency and output power at room temperature.

In a QCL, many of the parameters, which influence light emission and electronic transport, such as dipole matrix elements and electronic energy level lifetimes, are not intrinsic properties of the semiconductor material but are determined by the heterostructure design, i.e. by the sequence of layer thicknesses and compositions. Therefore, laser characteristics such as threshold current density, output power, and wallplug efficiency (WPE), depend not only on the quality of the epitaxial growth and device processing, but also on the quantum design of the active region. This design flexibility, intrinsic to QCLs, allows designers to optimize lasers for a particular application by favoring one or more laser characteristics for given operating conditions. One such characteristic, which designers generally try to optimize, possibly together with other ones, is the device wallplug efficiency, defined as the electrical-to-optical power conversion efficiency. High wallplug efficiency is beneficial for most operating conditions as it results in low power consumption and low self-heating, which in turn lead to high output power, high reliability, etc. In this patent application, we describe an invention to maximize the wallplug efficiency of mid-infrared QCLs at room temperature.

QCL designers have the freedom to optimize several parameters for their particular application. An important parameter is the voltage defect Δ, defined as the energy difference between the lower laser level of one gain stage and the upper laser level of the next gain stage. This parameter is particularly relevant to laser performance in the long-wave infrared (LWIR) spectral range, from ˜7 to 12 μm, where the voltage defect is comparable to the photon energy, and in the very-long-wave infrared (VLWIR) range (λ>12 μm) where the voltage defect is typically larger than the photon energy.

Optimization of voltage defect consists in balancing two opposite effects. If Δ is too large, the device voltage will be too high, while if Δ is too low, it will result in an increased thermal backfilling of the lower laser level and, therefore, a lower population inversion and a higher threshold current density. Both of these effects are detrimental to the wallplug efficiency. The purpose of this invention is to determine the optimum design value of Δ for which the wallplug efficiency is maximal. This value is strongly dependent on the laser operating temperature. The discussion in this patent application concentrates on the particular case of room temperature, which is of special importance for most practical applications.

References discussing some background aspects include:
(a) J. Faist, Appl. Phys. Lett. 90, 253512 (2007) (“Faist”);
(b) S. S. Howard, Z. Liu, D. Wasserman, A. J. Hoffman, T. S. Ko, and C. F. Gmachl, IEEE J. Sel. Top. Quantum Electron. 13, 1054 (2007) (“Howard”); and
(c) Alexei Tsekoun, Rowel Go, Michael Pushkarsky, Manijeh Razeghi and C. Kumar N. Patel, Proc. Nat. Acad. Sciences 103, 4831-4835 (2006) (“Tsekoun”).

### DISCLOSURE OF INVENTION

A primary purpose of this invention is to maximize the wallplug efficiency of mid-infrared quantum cascade lasers at room temperature by optimizing their voltage defect. Accordingly, one aspect of the invention can be generally described as a quantum cascade laser having a lower laser level backfilling (nₜₕₑᵣₘ) given by the equation

$${n}_{therm} = {n}_{s} {e}^{- \frac{Δ}{2 kT}} \frac{sinh [ \frac{Δ}{2 {N}_{inj} k T} ]}{sinh [ \frac{( {N}_{inj} + 1 ) Δ}{2 {N}_{inj} k T} ]} ,$$

where nₛ is the sheet carrier density per gain stage, T is the temperature, k is the Boltzmann constant, Δ is the voltage defect, and Nᵢₙⱼ is the number of injector subbands. Accordingly, this equation accounts for the degeneracy of the energy states due to the presence of multiple subbands. For quantum cascade lasers having a wavelength of 7 μm and where T is room temperature, and Nᵢₙⱼ is 8, the voltage defect is between 90 meV and 100 meV at a current density of (0.8)J_{max,} where Jₘₐₓ is the rollover current density.

Another aspect of the invention can be generally described as a quantum cascade laser having a lower laser level backfilling (nₜₕₑᵣₘ) given by the equation

$${n}_{therm} = \frac{1}{{N}_{inj} + 1} {\int }_{Δ}^{∞} n ( E ) d E ,$$

where Nᵢₙⱼ is the number of injector subbands and n(E) is the carrier density per unit energy per unit area.

### BRIEF DESCRIPTION OF DRAWINGS

FIG. 1 shows the calculated maximum wallplug efficiency of a 7.1 μm quantum cascade laser as a function of the voltage defect Δ. The lower laser level backfilling was computed using the model presented in this patent application. The inset shows backfilling of the lower laser level as a function of voltage defect calculated with the traditional single-subband model and with the new model disclosed in this patent application.

The bottom portion of FIG. 2 shows the measured voltage, optical output power, and wallplug efficiency as a function of current in pulsed mode at 293 K of a quantum cascade laser with optimized voltage defect emitting at 7.1 μm. The top portion of FIG. 2 shows the measured voltage defect of the same laser as a function of current (same horizontal scale).

### BEST MODE FOR CARRYING OUT THE INVENTION

The detailed description set forth below in connection with the appended drawings is intended as a description of presently-preferred embodiments of the invention and is not intended to represent the only forms in which the present invention may be constructed or utilized. The description sets forth the functions and the sequence of steps for constructing and operating the invention in connection with the illustrated embodiments. However, it is to be understood that the same or equivalent functions and sequences may be accomplished by different embodiments that are also intended to be encompassed within the spirit and scope of the invention.

As discussed above, one of the critical design parameters, which influence QCL wallplug efficiency, is the voltage defect Δ. The Faist and Howard references predicted optimal voltage defects of 150 meV and 175 meV, respectively, for room temperature operation. Both of these authors described backfilling of the lower laser level as nₜₕₑᵣₘ=nₛ exp(−Δ/k1), where nₛ is the sheet carrier density per gain stage, T is the temperature, and k is the Boltzmann constant.

This formula implicitly assumes a constant density of states in the injector, i.e. an injector consisting of a single subband. Here we introduce a more refined model, which takes into account the number of subbands in the injector and leads to a better optimum value for the voltage defect.

We assume that the energy levels of the injector states are equally spaced by ΔEᵢₙⱼ=Δ/Nᵢₙⱼ, where Nᵢₙⱼ is the number of injector subbands (=numbers of subbands below the lower laser level per gain stage). Neglecting non-parabolicity, the two-dimensional density of states can be written as:

$$D ( E ) = {D}_{0} {\sum }_{i = 0}^{{N}_{inj}} θ ( E - i \cdot Δ {E}_{inj} ) ,$$

where D₀ is the density of states of one subband and θ is the Heaviside step function. Assuming a thermal distribution of carriers in the injector, the carrier density per unit energy, per unit area is

$$n ( E ) = \frac{{n}_{s}}{Z} D ( E ) f ( E ) ,$$

where f(E) is the Fermi-Dirac distribution and Z=∫₀^{∞}D(E)f(E)dE is the partition function. Due to the low carrier density in QCLs, f(E) can be approximated by the Boltzmann distribution exp(−Elk′l). The lower laser level backfilling is calculated as:

$${n}_{therm} = \frac{1}{{N}_{inj} + 1} {\int }_{Δ}^{∞} n ( E ) d E ,$$

where the 1/(Nᵢₙⱼ+1) factor accounts for the degeneracy of the energy states due to the presence of multiple subbands. Calculations can be performed analytically in the case of the Boltzmann distribution, resulting in the following formula for backfilling:

$${n}_{therm} = {n}_{s} {e}^{- \frac{Δ}{2 kT}} \frac{sinh [ \frac{Δ}{2 {N}_{inj} k T} ]}{sinh [ \frac{( {N}_{inj} + 1 ) Δ}{2 {N}_{inj} k T} ]} .$$

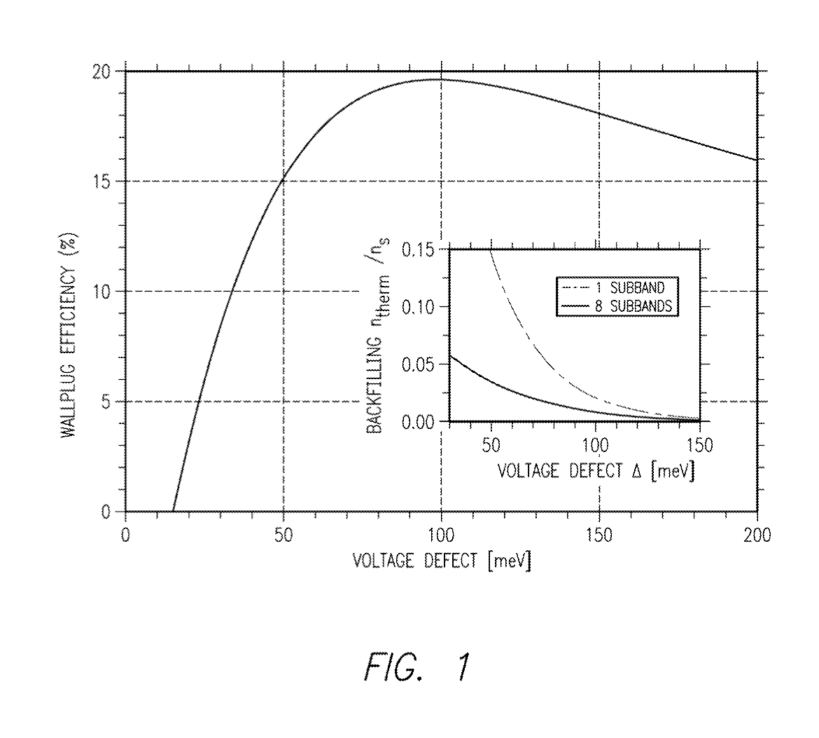

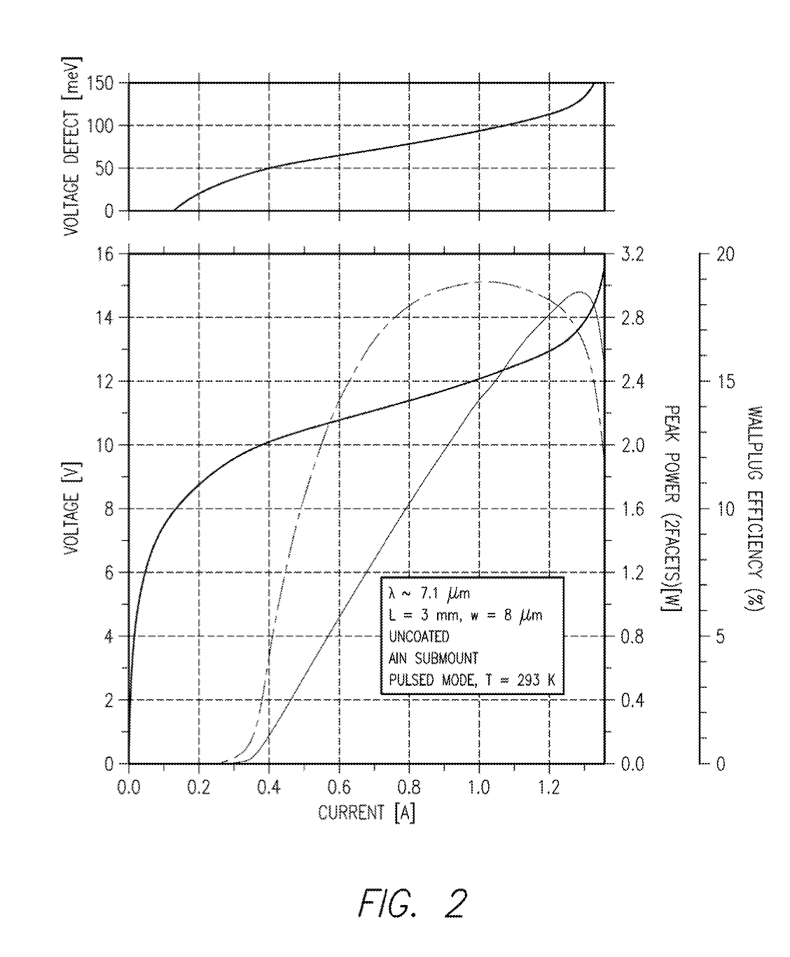

nₜₕₑᵣₘ/nₛ as a function of Δ at T=300 K obtained with this model and with the usual approximation are plotted in the inset in FIG. 1. Comparing the two, we find that, for a typical number of injector subbands Nᵢₙⱼ=8, the single-subband approximation overestimates the backfilling by factors of ˜2, 2.5, and 4 for Δ=150, 100, and 5.0 meV, respectively.

We now apply our refined model to determine the voltage defect which maximizes wallplug efficiency at room temperature. The WPE as a function of Δ at T=300 K is plotted in FIG. 1 for Nᵢₙⱼ=8 and for a wavelength of 7.1 μm, using the same numerical parameters as in the Faist reference. The maximum WPE is predicted for Δ˜100 meV, which is significantly lower than the values given in the Faist and Howard references. The model predicts optimum voltage defect values between 95 meV and 110 meV at all mid-infrared QCL wavelengths between 3.5 μm and 17 μm.

Our model reveals a dependence of backfilling on the number of subbands in the injector, with a noticeable decrease of nₜₕₑᵣₘ with increasing Nᵢₙⱼ. For a typical Nᵢₙⱼ of 8, this translates into a significant reduction of the optimum value of Δ, which results in an increased WPE, especially in the LWIR where the photon energy is comparable to the voltage defect and in the VLWIR where the photon energy is smaller than the voltage defect.

We designed a 7 μm-wavelength room temperature QCL with a voltage defect of 100 meV. The structure was designed so that the optimal voltage defect of 100 meV is reached a little bit before the power roll-over, at a current density J≅0.8·Jₘₐₓ, where Jₘₐₓ is the roll-over current density, because we typically observe a decrease of carrier injection efficiency into the upper laser level close to Jₘₐₓ at room temperature, which results in a decrease in slope efficiency.

The InGaAs/AlInAs active region and InP claddings forming the structure were grown by molecular beam epitaxy on an InP substrate. The epi-wafer was processed into buried heterostructure lasers and cleaved into chips, which were then mounted epi-side down on AlN submounts with AuSn solder. Low-duty-cycle pulsed testing was performed at chip-on-carrier level. Devices were pulsed at 10 kHz repetition rate with a pulse width of 500 ns and the output power was measured with a calibrated thermopile detector placed directly in front of the output facet. Peak output power (for two facets), voltage, and WPE as function of current of an uncoated 3 mm×8 μm chip at a temperature of 293 K are shown in the main panel of FIG. 2. The threshold and roll-over current densities are 1.45 and 5.38 kA/cm², respectively. The slope efficiency is 3.59 W/A, and the maximum WPE 18.9%. This is the highest wallplug efficiency reported for any QCLs operating at room temperature in this wavelength range. The top panel of FIG. 2 shows the measured voltage defect Δ=eV/Nₚ−hv, where e is the elementary charge, V is the measured voltage drop across the entire structure, Nₚ=45 is the number of gain stages, and hv=175 meV is the photon energy, as a function of current. The voltage defect at maximum WPE is measured to be ˜95 meV. This is in good agreement with our model, which predicts a maximum WPE for Δ≅100 meV at room temperature.

In conclusion, we designed and fabricated room temperature quantum cascade lasers with a voltage defect of ˜100 meV, which is significantly lower than previously reported in the literature for room-temperature or near-room-temperature operation. These lasers demonstrated record-high wallplug efficiency at room temperature. The utilization of the same voltage defect will also result in wallplug efficiency improvements at other wavelengths. The wallplug efficiency gain will be most significant for long-wave infrared and very-long-wave infrared quantum cascade lasers.

While the present invention has been described with regards to particular embodiments, it is recognized that additional variations of the present invention may be devised without departing from the inventive concept.

### INDUSTRIAL APPLICABILITY

This invention may be industrially applied to the development, manufacture, and use of quantum cascade lasers.

What is claimed is:

1. A quantum cascade laser with a voltage defect at a given temperature (T) and characterized by a wallplug efficiency, the quantum cascade laser including a quantum cascade laser injector and having a number of subbands in the quantum cascade laser injector, where the voltage defect is optimized to maximize the wallplug efficiency at T using a model to account for the number of subbands in the quantum cascade laser injector.

2. The quantum cascade laser of claim 1, where T is room temperature.

3. The quantum cascade laser of claim 1, the quantum cascade laser having a wavelength of 7 μm and a rollover current density (Jₘₐₓ), and where T is room temperature and the voltage defect is between 90 meV and 110 meV at a current density of (0.8)Jₘₐₓ.

4. The quantum cascade laser of claim 1, the quantum cascade laser having a wavelength between (and including) 3.5 μm and 17 μm and a rollover current density (Jₘₐₓ), and where T is room temperature and the voltage defect is between 90 meV and 110 meV at a current density of (0.8)Jₘₐₓ.

5. The quantum cascade laser of claim 1, the quantum cascade laser further characterized by a lower laser level backfilling (nₜₕₑᵣₘ), where the model represents nₜₕₑᵣₘ by the equation
$${n}_{therm} = {n}_{s} {e}^{- \frac{Δ}{2 kT}} \frac{sinh [ \frac{Δ}{2 {N}_{inj} k T} ]}{sinh [ \frac{( {N}_{inj} + 1 ) Δ}{2 {N}_{inj} k T} ]} ,$$
where nₛ is the sheet carrier density per gain stage, T is the temperature, k is the Boltzmann constant, Δ is the voltage defect, and Nᵢₙⱼ is the number of injector subbands.

6. The quantum cascade laser of claim 2, where T is room temperature.
